(19) United States
(12) Patent Application Publication
(10) Pub. No.: US 2014/0213034 A1
(43) Pub. Date: Jul. 31, 2014

(54) METHOD FOR FORMING ISOLATION STRUCTURE

(71) Applicant: UNITED MICROELECTRONICS CORP., Hsin-Chu City (TW)

(72) Inventors: Chia-Lung Chang, Tainan City (TW); Chih-Chien Liu, Taipei City (TW); Jei-Ming Chen, Tainan City (TW); Wen-Yi Teng, Kaohsiung City (TW); Jui-Min Lee, Taichung City (TW); Keng-Jen Lin, Kaohsiung City (TW); Chin-Fu Lin, Tainan City (TW)

(73) Assignee: UNITED MICROELECTRONICS CORP., Hsin-Chu City (TW)

(21) Appl. No.: 13/752,408

(22) Filed: Jan. 29, 2013

(51) Int. Cl. H01L 21/762

(52) U.S. Cl. CPC H01L 21/76224
USPC 438/424

(57) ABSTRACT

A method for forming an isolation structure includes the following steps. A hard mask layer is formed on a substrate and a trench is formed in the substrate and the hard mask layer. A protective layer is formed to cover the trench and the hard mask layer. A first isolation material is filled into the trench. An etching process is performed to etch back part of the first isolation material.

### BACKGROUND OF THE INVENTION

1. Field of the Invention

The present invention relates generally to a method for forming an isolation structure, and more specifically to a method for forming an isolation structure by forming a protective layer and etching back an isolation material.

2. Description of the Prior Art

Since the integrated circuit devices size evolves towards smaller dimensions with increased integration rates, distances and arrangements between devices within a semiconductor substrate are decreasing and become tighter. Therefore, suitable isolation has to be formed between each device to avoid junction current leakage, and an insulating or isolation region has to be reduced in order to enhance integration with improved isolation. In various device isolation technologies, localized oxidation isolation(LOCOS) and shallow trench isolation (STI) are the most often used techniques. In particular, the STI has the advantages of a smaller isolation region and retaining planarization of the semiconductor substrate. The prior art STI structure is formed between two metal oxide semiconductor (MOS) transistors and surrounds an active region in the semiconductor substrate to prevent carriers, such as electrons or electric holes, from drifting between two adjacent devices through the substrate which causes junction current leakage. STI not only isolate such device effectively but are also inexpensive, which suits semiconductor processes with high integration. As semiconductor processes develop, the demand for isolation structures become more critical. Thus, forming an isolation structure having good qualities has become an important issue.

### SUMMARY OF THE INVENTION

The present invention provides a method for forming an isolation structure, which etches back a part of an isolation material to remove or expose voids therein, forms a protective layer before the etching process is performed to further prevent a substrate and a hard mask layer from being damaged during the etching process, and then transforms the protective layer into a part of the isolation material, thereby enhancing the qualities and reliabilities of the isolation structure.

The present invention provides a method for forming an isolation structure including the following steps. A hard mask layer is formed on a substrate and a trench is formed in the substrate and the hard mask layer. A protective layer is formed to cover the trench and the hard mask layer. A first isolation material is filled into the trench. An etching process is performed to etch back part of the first isolation material.

According to the above, the present invention provides a method for forming an isolation structure including the following. A hard mask layer is formed on a substrate and a trench is formed in the substrate and the hard mask layer. A protective layer is formed to cover the trench and the hard mask layer. A first isolation material is filled into the trench, wherein the hard mask layer and the substrate are isolated from the first isolation material thanks to the protective layer, but voids will be generated in the first isolation material. Thus, an etching process is performed to etch back parts of the first isolation material to expose or remove the voids. In this way, the voids in the first isolation material can be exposed or removed by etching back the first isolation material. The substrate and the hard mask layer can isolate the first isolation material by forming the protective layer before the etching process is performed. Therefore, the substrate and the hard mask layer can be protected from being damaged by the etching process, especially, the material of some parts of the hard mask layer, such as a pad oxide layer, similar to the material of the first isolation material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 schematically depict cross-sectional views of a method for forming an isolation structure according to an embodiment of the present invention.

FIG. 9 schematically depicts a cross-sectional view of a method for forming an isolation structure according to another embodiment of the present invention.

### DETAILED DESCRIPTION

FIGS. 1-8 schematically depict cross-sectional views of a method for forming an isolation structure according to an embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. A hard mask layer (not shown) is formed on the substrate 110. In this embodiment, the hard mask layer (not shown) includes a pad oxide layer (not shown) and a nitride layer (not shown) stacked from bottom to top, but it is not limited thereto. An etching process is performed to pattern the nitride layer (not shown) and the pad oxide layer (not shown), and a mask layer 120 is formed, including a pad oxide layer 122 and a nitride layer 124 from bottom to top, so that the position of a trench formed in the substrate 110 is defined. An etching process is performed to form a trench R in the substrate 110. This means the hard mask layer 120 is formed on the substrate 110, and the trench R is formed in the substrate 110 and the hard mask layer 120.

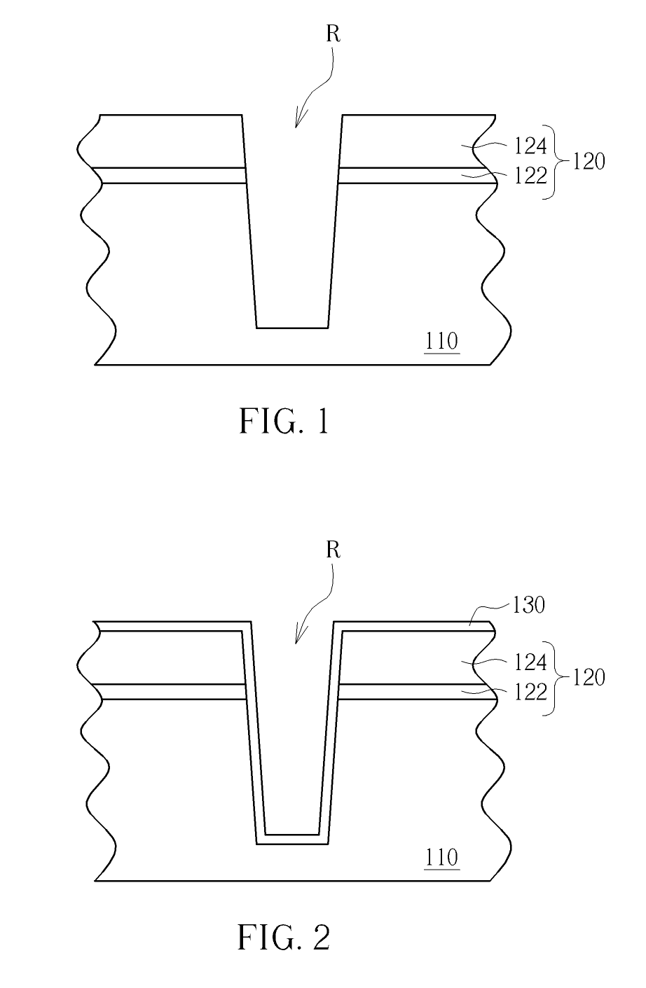

As shown in FIG. 2, a protective layer 130 is formed to cover the trench R and the hard mask layer 120. In this embodiment, the protective layer 130 is a silicon layer. In another embodiment, the protective layer 130 may be a non-oxide layer for isolating the substrate 110 and the hard mask layer 120 from isolation materials filling the trench R. In general, the isolation materials are oxygen containing materials, so the protective layer is preferably an non-oxide layer, which has better etching selectivity to the isolation materials during later performed etching processes; i.e. the etching rate of an etching process to the protective layer is different from the etching rate to the isolation materials, so that the substrate 110 and the hard mask layer 120 can be isolated from the isolation materials well. In this embodiment, the protective layer 130 is formed through a plasma enhanced chemical vapor deposition (PECVD) process or an atomic layer deposition (ALD) process, but it is not limited thereto, so that the recess R and the hard mask layer 120 can be protected by the protective layer 130 in an effective way.

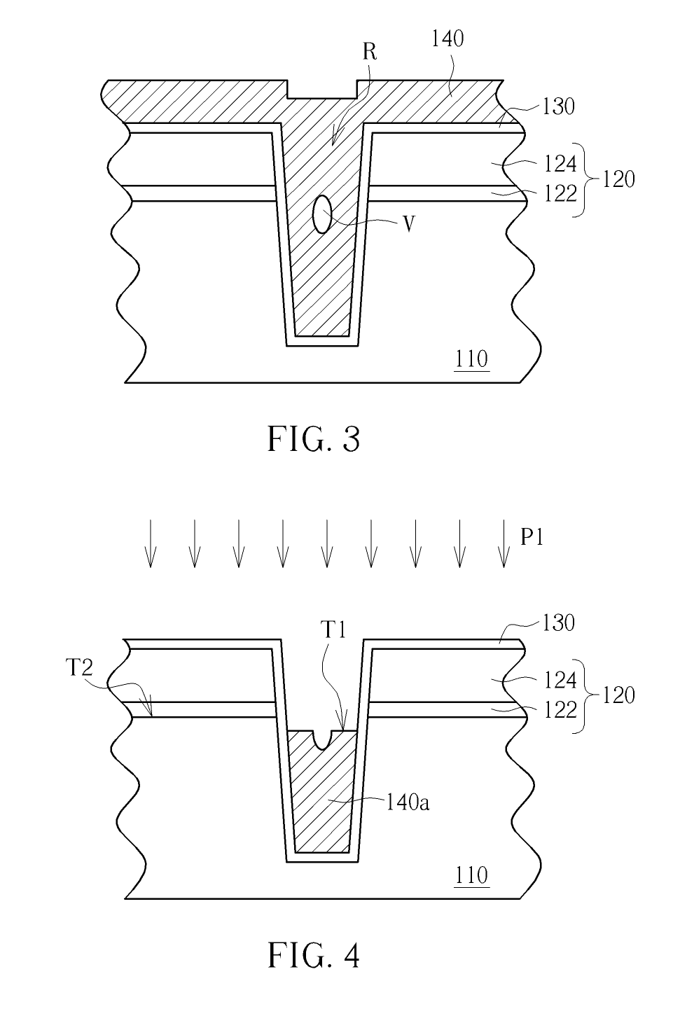

As shown in FIG. 3, a first isolation material 140 is filled into the trench R. In one case, the first isolation material 140 will fill up the trench R and cover the protective layer 130 on the hard mask layer 120. Moreover, the first isolation material 140 is an oxide for forming a shallow trench isolation structure, but it is not limited thereto. In another embodiment, the first isolation material 140 may be other materials, and the first isolation material 140 is used to form other isolation structures. In this embodiment, the first isolation material 140 is formed through a chemical vapor deposition (CVD) process such as a high aspect ratio process (HARP), but it is not limited thereto. The shallow trench isolation structure may have voids V form therein according to the aspect ratio of the shallow trench isolation structure and the gap filling capability of deposition processes, that affect the results of later performed processes such as wet etching processes. In nowadays processes, the first isolation material 140 will have voids V formed therein. In order to simplify the description of the present invention, only one void v will be described, but the number of voids v may be more than one, depending upon practical circumstances. Even more, the present invention can also be applied in a shallow trench isolation structure having no voids V therein.

As shown in FIG. 4, an etching process P1 is performed to etch back parts of the first isolation material 140 until the void V is exposed, or until the void V is removed. This way, parts of the first isolation material 140 may be etched back deeper than the void V. In this embodiment, a top surface T1 of a first isolation material 140a being back etched is lower than the level of a bottom surface T2 of the hard mask layer 120 to expose the void V, but it is not limited thereto. The etching process P1 maybe a dry etching process or/and a wet etching process. The etching rate of the etching process P1 to the first isolation material 140 is larger than the etching rate to the protective layer 130.

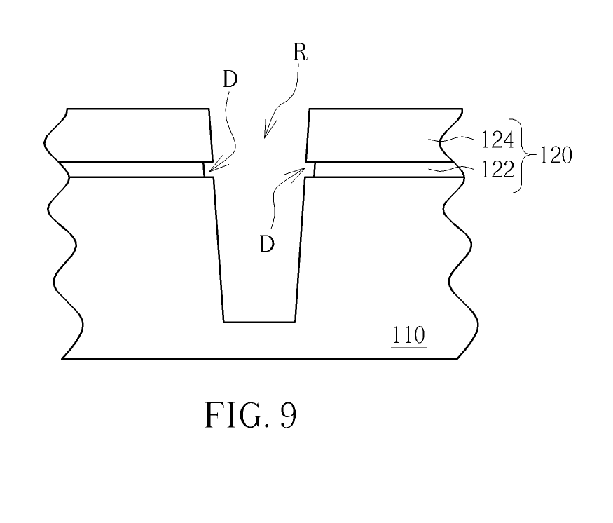

Since the protective layer 130 is formed and covers the trench R in the present invention so as to isolate the hard mask layer 120 and the substrate 110 from the first isolation material 140, damages in the hard mask layer 120 or the substrate 110 during the etching process Pican be avoided. More particularly, the first isolation material 140 is generally an oxide material, and the pad oxide layer 122 of the hard mask layer 120 is also an oxide, so the pad oxide layer 122 may be etched simultaneously and may laterally shrink as shown in FIG. 9. However, the pad oxide layer 122 will be protected from being etched and laterally shrink thanks to the protective layer 130 in the present invention. As shown in FIG. 9, there is no protective layer 130 covering the trench R and the hard mask layer 120, so that the damages in the nitride layer 124, the pad oxide layer 122 and the substrate 110 occur because of the exposure of the nitride layer 124, the pad oxide layer 122 and the substrate 110. Moreover, due to the exposed pad oxide layer 122 having a similar material to that of the first isolation material 140, the pad oxide layer 122 is etched more than the nitride layer 124 and the substrate 110, leading to the formation of divots D between the nitride layer 124 and the substrate 110. The divots D will degrade the performances of the formed isolation structure and therefore reduce the reliability of the formed semiconductor component.

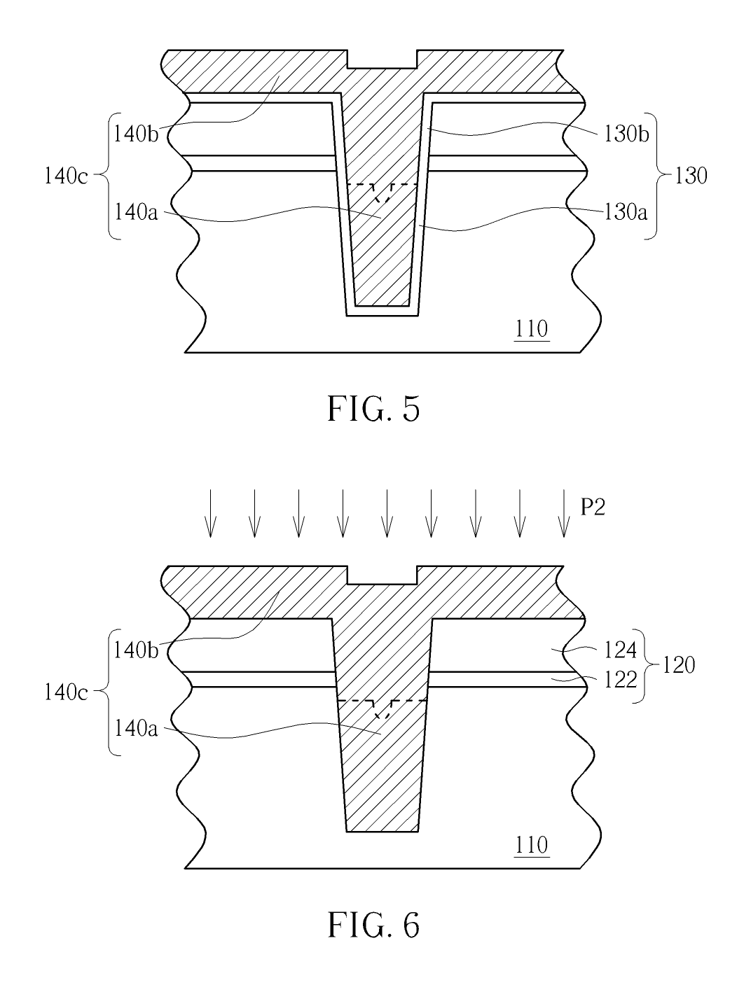

As shown in FIG. 5, a second isolation material 140b is filled on the first isolation material 140a in the trench R. In a preferred embodiment, the first isolation material 140a and the second isolation material 140b are the same materials so as to form an isolation material 140c of one piece and with a dense structure, and the protective layer 130 can be completely transformed into a part of the first isolation material 140a and the second isolation material 140b in later processes, but it is not limited thereto.

Then, the protective layer 130 is transformed into parts of the first isolation material 140a and the second isolation material 140b, as shown in FIG. 6. In one embodiment, the first isolation material 140a and the second isolation material 140b are of the same material, and the protective layer 130 is therefore completely transformed into a part of the first isolation material 140a and the second isolation material 140b. In this embodiment, the first isolation material 140a and the second isolation material 140b may all be oxides, such as silicon dioxide, and the protective layer 130 is a silicon layer, so that the silicon layer can be transformed into an oxide layer, such as a silicon dioxide layer, through processes such as an annealing process P2, to become a part of the first isolation material 140a and the second isolation material 140b, wherein the processing temperature of the annealing process P2 is preferably 700° C.˜1000° C. but it is not limited thereto. Moreover, the annealing process P2 may be performed in a higher processing temperature, or/and in an oxygen or vapor containing environment to transform the protective layer 130 completely. In another embodiment, the first isolation material 140a and the second isolation material 140b may be different or similar materials, so that the a lower part 130a of the protective layer 130 contacting the first isolation material 140a and an upper part 130b of the protective layer 130 contacting the first isolation material 140b (as shown in FIG. 5) can be transformed into a part of the first isolation material 140a and the second isolation material 140b respectively during the same or different processes. In this way, the protective layer 130 will not remain on the hard mask layer 120, and thus the risk that the hard mask layer 120 can not be removed due to the protective layer 130 covered thereon can be avoided.

The thickness of the protective layer 130 is chosen to be thick enough to be an etch stop layer while the etching process P1 is performed, and can be transformed to a part of the first isolation material 140a and the second isolation material 140b completely during the annealing process P2. In one case, the thickness of the protective layer 130 is preferably 30˜50 angstroms.

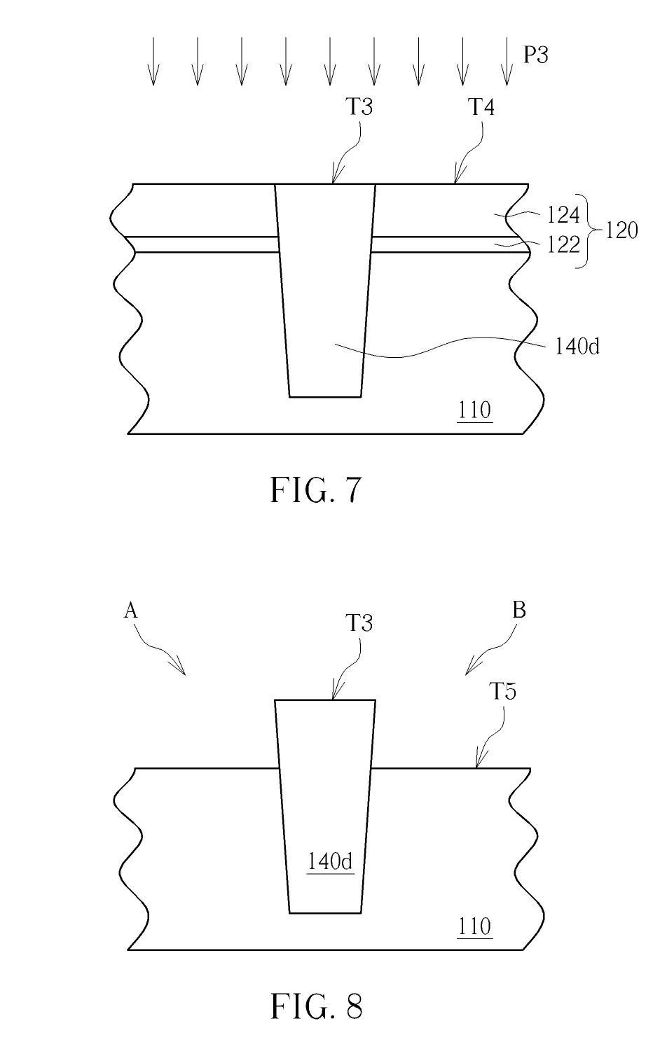

A polishing process P3 is performed to polish the second isolation material 140b until the hard mask layer 120 is exposed, and an isolation structure 140d is therefore formed as shown in FIG. 7. Since the protective layer 130 is transformed into a part of the first isolation material 140a and/or the second isolation material 140b in the previous steps, which means that the protective layer 130 after transformation and the first isolation material 140a and/or the second isolation material 140b have similar polishing rates, so the hard mask layer 120 can be exposed after the polishing process P3 using the hard mask layer 120 as a stop layer. Thus, a top surface T3 of the isolation structure 140d will be on the same level as a top surface T4 of the hard mask layer 120. The polishing process P3 may be a chemical mechanical polishing (CMP) process, but it is not limited thereto.

Thereafter, the hard mask layer 120 is removed to expose the substrate 110 as shown in FIG. 8. Thus, the top surface T3 of the isolation structure 140d is now higher than the level of a top surface T5 of the substrate 110. Then, semiconductor processes such as the kind for forming MOS transistors on two active sides A and B of the substrate 110 beside the isolation structure 140d can be performed, wherein the semiconductor components formed on the active sides A and B can be electrically isolated by the isolation structure 140d.

To summarize, the present invention provides a method for forming an isolation structure including the following. A hard mask layer is formed on a substrate and a trench is formed in the substrate and the hard mask layer. A protective layer is formed to cover the trench and the hard mask layer. A first isolation material is filled into the trench, so that the hard mask layer and the substrate are isolated from the first isolation material by the protective layer, but voids will be generated in the first isolation material. Thus, an etching process is performed to etch back parts of the first isolation material to expose or remove the voids. Then, a second isolation material may be filled on the first isolation material into the trench; the protective layer is transformed into a part of the first isolation material or/and the second isolation material to form the isolation structure, wherein the transforming process may be an annealing process. In this way, the voids in the first isolation material can be exposed or removed through etching back the first isolation material and filling the second isolation material. The substrate and the hard mask layer can be isolated from the first isolation material by forming the protective layer before the etching process is performed. Therefore, the substrate and the hard mask layer can be protected from being damaged during the etching process; especially, when the material of a part of the hard mask layer such as a pad oxide layer is similar to the material of the first isolation material. Moreover, the protective layer is transformed into a part of the first isolation material or/and the second isolation material, so the isolation structure without protective layer residue is formed, thereby solving the problem of the incapacity to completely remove the hard mask layer. Furthermore, the method of forming the protective layer in the present invention can also be applied in the first isolation material without voids formed therein, to prevent the substrate and the hard mask from being damaged while etching such as the aforesaid deposition-etching-deposition process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming an isolation structure, comprising:
forming a hard mask layer on a substrate and a trench in the substrate and the hard mask layer;
forming a protective layer to cover the trench and the hard mask layer;
filling a first isolation material in the trench; and
performing an etching process to etch back parts of the first isolation material.

2. The method for forming an isolation structure according to claim 1, wherein the isolation structure comprises a shallow trench isolation structure.

3. The method for forming an isolation structure according to claim 1, wherein the protective layer comprises a non-oxide layer.

4. The method for forming an isolation structure according to claim 1, wherein the protective layer comprises a silicon layer.

5. The method for forming an isolation structure according to claim 1, wherein the protective layer is formed through a plasma enhanced chemical vapor deposition (PECVD) process.

6. The method for forming an isolation structure according to claim 1, wherein the hard mask layer comprises a pad oxide layer and a nitride layer stacked from bottom to top.

7. The method for forming an isolation structure according to claim 1, wherein the first isolation material is formed through a chemical vapor deposition (CVD) process.

8. The method for forming an isolation structure according to claim 1, wherein the first isolation material comprises oxide.

9. The method for forming an isolation structure according to claim 1, wherein a top surface of the back etched first isolation material is lower than the level of a bottom surface of the hard mask layer.

10. The method for forming an isolation structure according to claim 1, wherein the first isolation material comprises at least avoid, and the first isolation material is etched back until at least a void is exposed.

11. The method for forming an isolation structure according to claim 1, wherein the etching rate of the etching process to the first isolation material is higher than the etching rate to the protective layer.

12. The method for forming an isolation structure according to claim 1, further comprising:
filling a second isolation material on the first isolation material in the trench after the first isolation material is etched back.

13. The method for forming an isolation structure according to claim 12, wherein the second isolation material is formed through a chemical vapor deposition (CVD) process.

14. The method for forming an isolation structure according to claim 12, wherein the first isolation material and the second isolation material are the same materials.

15. The method for forming an isolation structure according to claim 12, further comprising:
transforming the protective layer into a part of the first isolation material or the second isolation material after the second isolation material is filled.

16. The method for forming an isolation structure according to claim 15, wherein the protective layer is transformed into a part of the first isolation material or the second isolation material by performing an annealing process.

17. The method for forming an isolation structure according to claim 16, wherein the processing temperature of the annealing process is 700° C.˜1000° C.

18. The method for forming an isolation structure according to claim 15, further comprising:
performing a polishing process to polish the second isolation material until the hard mask layer is exposed after the protective layer is transformed into a part of the first isolation material or the second isolation material.

19. The method for forming an isolation structure according to claim 18, further comprising:
removing the hard mask layer after the polishing process is performed.
